(19) United States
(12) Patent Application Publication
(10) Pub. No.: US 2017/0067155 A1
(43) Pub. Date: Mar. 9, 2017

(54) VAPOR DEPOSITION DEVICE AND METHOD EMPLOYING PLASMA AS AN INDIRECT HEATING MEDIUM

(71) Applicant: CPFilms Inc., Fieldale, VA (US)

(72) Inventors: Jaime Antonio Li, Martinsville, VA (US); Coby Lee Hubbard, Patrick Springs, VA (US); David Lee Richardson, Stuart, VA (US)

(73) Assignee: CPFILMS INC., Fieldale, VA (US)

(21) Appl. No.: 14/847,050

(22) Filed: Sep. 8, 2015

(51) Int. Cl. C23C 16/448; C23C 16/54; C23C 14/56

(52) U.S. Cl. CPC C23C 16/4485; C23C 14/562; C23C 16/545

(57) ABSTRACT

A vapor deposition device and a method for depositing a coating on a substrate are disclosed. The device includes a heating chamber for containing plasma and an evaporant chamber for containing an evaporant source. Evaporant is generated by heating of the evaporant source by the plasma. The heating chamber is both separated from the evaporant chamber and in thermally conductive connectivity with the evaporant chamber. The method includes supplying plasma to a heating chamber; heating an evaporant source by transfer of heat from the plasma to in an amount sufficient to generate evaporant from the evaporant source; and condensing the evaporant or a reaction product thereof on a surface of the substrate to form a coating thereon. The plasma is maintained in isolation from the evaporant source and the evaporant.

### FIELD OF THE INVENTION

The present invention relates to device and method for forming a coating on a substrate using vapor deposition.

### BACKGROUND OF THE INVENTION

Vapor deposition is a well-known and widely used technology for coating of substrates, especially in technical fields where thin (<1 micron thickness) coatings with high uniformity, low defect rate and other demanding performance characteristics are required. Vapor deposition processes typically involve in the broadest sense the formation of an evaporant by applying energy such as heat to an evaporant source then forming a coating on a substrate through condensation of the evaporant or a reaction product thereof to form a layer on the surface of the substrate.

In utilizing vapor deposition processes for coating substrates with coating materials such as metals or ceramics, temperatures in excess of 1000° C. are often required to generate evaporant from the evaporant source. For example, deposition of magnesium fluoride on a polymer film substrate requires heating of the magnesium fluoride evaporant source to a process temperature of over 1400° C. In prior art vapor deposition processes, such high-temperature heating is often achieved using resistive heating elements, often as part of a linear heater, to which a high current load (often tens or hundreds of amps or greater) is applied. Such current loads can be supplied only through large cables that are costly, bulky and require cooling during use. Further, delivery of such large loads at points on the heating element often generate an undesirable temperature gradient along the element. Use of linear resistance heaters to generate evaporant from the evaporant source also suffer from the disadvantage of uneven temperature gradients and evaporant flux distribution due to the required cooling of the connecting cables.

Plasma can be used as heat or energy source in processes requiring even application of energy or heat over an extended area, including coating processes such as vacuum deposition. For example, as disclosed U.S. Pat. No. 6,444,945, plasma is generated in a gas which is combined with emissions from a vacuum deposition source to form a coating on a substrate (see column 9 at line 64). More generally, plasma can be used in conjunction with physical vapor deposition in known “plasma-enhanced physical vapor deposition” (PEPVD) processes or “plasma-enhanced chemical vapor deposition” (PECVD) processes. In both prior art processes, the plasma contacts and interacts or reacts with one or more of the evaporant, the evaporant source and substrate to be coated.

While such interactions and reactions are sometimes an intended component of such coating process, in others they can produce unintended and detrimental effects. For example, reactions between the evaporant and the plasma can fundamentally change the chemical structure of or degrade the evaporant, with the resulting coating layer being either of different composition than what was intended or of inferior quality. Similarly, contact and reaction between the evaporant source and the plasma can undesirably change the chemical makeup of the evaporant source at its surface before evaporant is formed, thereby again changing the nature or quality of the resulting coating. In addition, contact and interaction of the plasma with the evaporant may have a negative effect on the properties of the plasma. Such changes in the plasma and/or coating are particularly problematic in processes wherein the composition of the coating is intended to match the composition of the evaporant and evaporant source. Further, under certain conditions, plasma can damage the substrate to be coated and therefore the quality of the final coated product. Also, in processes and devices where electrodes required for generating the plasma are exposed to the evaporant, unintended deposition of the evaporant onto these electrodes can hinder the plasma generation process as well as reduce coating efficiency. As a more general matter in these processes, coating variations and substrate damage can be caused by non-uniform temperature gradients and plasma conditions in the process region.

A continuing need therefore exists in the art for improved vapor deposition devices and processes that efficiently produce high-quality, uniform coatings of the desired composition on substrates.

### SUMMARY OF THE INVENTION

The present invention relates to a vapor deposition device that utilizes plasma as an indirect heating medium to generate evaporant from an evaporant source. The device includes a heating chamber for containing the plasma and an evaporant chamber for containing an evaporant source. Evaporant is generated in the evaporant chamber by heating of the evaporant source by the plasma. The heating chamber is both separated from the evaporant chamber and in thermally conductive connectivity with the evaporant chamber.

The present invention further relates to a method for depositing a coating on a substrate, the method including supplying plasma to a heating chamber; applying heat from the plasma to an evaporant source in an amount sufficient to generate evaporant from the evaporant source; and condensing the evaporant or a reaction product thereof on a surface of a substrate to form a coating thereon; wherein the plasma is maintained in isolation from the evaporant source and the evaporant.

By its separation of the heating chamber from the evaporant chamber and corresponding isolation of the plasma from the evaporant and evaporation source, the device and method of the present invention eliminate the drawbacks associated with the contact, interaction and potential reaction of the plasma with the evaporant and evaporant source.

Further aspects of the invention are as disclosed and claimed herein.

### BRIEF DESCRIPTION OF THE DRAWINGS

FIG. 1 is a schematic depiction in partial cross-section of an embodiment of the vapor deposition device of the present invention including the evaporant generation assembly of the present invention;

FIG. 2 is a schematic depiction in partial cross-section of an embodiment of the evaporant generation assembly of the present invention;

FIG. 3 is a schematic depiction in partial cross-section of an embodiment of the of the evaporant generation assembly of the present invention wherein the assembly includes multiple heating chambers and a single evaporant chamber; and

FIG. 4 is a schematic depiction in partial cross-section of an embodiment of the evaporant generation assembly of the present invention wherein the assembly includes a plasma source, a single heating chamber and multiple evaporant chambers.

### DETAILED DESCRIPTION

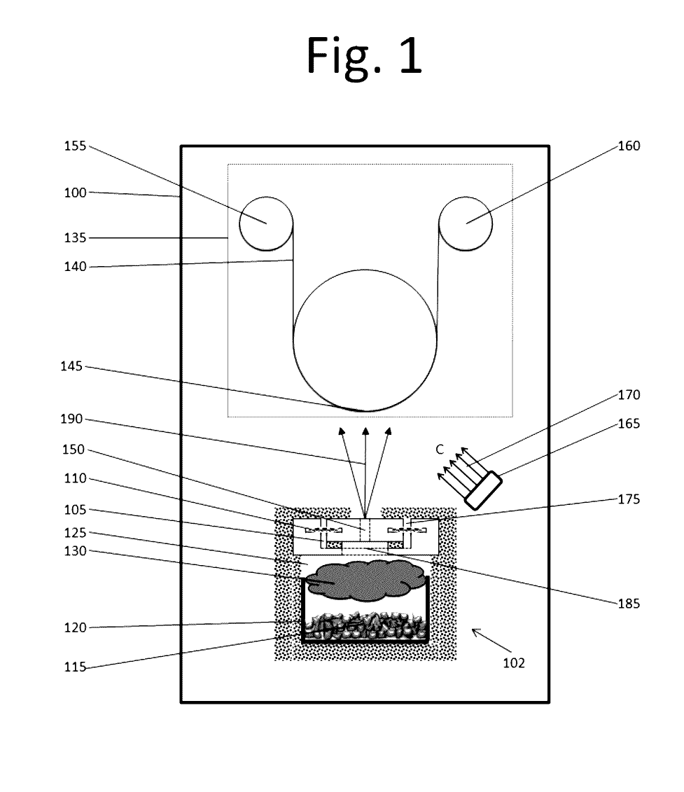

As illustrated in FIGS. 1 through 4, a first aspect of the present invention is directed to a vapor deposition device that utilizes plasma as an indirect heating medium to generate evaporant from an evaporant source. The vapor deposition device 100 of the present invention includes an evaporant generation assembly 102. Assembly 102 includes a heating chamber 105 for containing plasma (generally shown at 110); an evaporant source 115; and an evaporant chamber 125 containing the evaporant source 115. Evaporant (generally shown inside the evaporant chamber at 130 and exiting the evaporant generation assembly 102 through aperture 150 as streams 190) is generated from the evaporant source 115 by heating of the evaporant source 115 by the plasma 110. Depending on the physical state and type of evaporant source 115, it may be placed directly within the chamber 125 or may be retained in an optional evaporant source retainer 120 which, when in use, retains the evaporant source 115. Evaporant source retainer 120 may for example, be a crucible if the evaporant source is flowable material or a liner if the evaporant source is a solid that is preferably isolated from contact with the evaporant chamber 125.

An important aspect of the device of the present invention is that the heating chamber 105 is separated from the evaporant chamber 125. Further, as heat energy from the plasma is used to heat the evaporant source to form evaporant, the heating chamber 105 is in thermally conductive connectivity with the evaporant chamber. As used herein regarding the relationship between the heating chamber and the evaporant chamber, the term “separated from” means that the space or volume contained by the heating chamber is discrete from the space or volume contained by the evaporant chamber such that plasma does not and cannot physically contact or interact or chemically react with either the evaporant or the evaporant source to the extent either are present in the evaporant chamber 125. As used herein regarding the relationship between the heating chamber and the evaporant source, the phrase “in thermally conductive connectivity with” means that heat energy can be transferred through one or more heat transfer mechanisms between the plasma in the heating chamber and the evaporant source contained in the evaporant chamber.

As the device of the present invention is useful for applying a coating to (or forming a coating on) a substrate, the device of the present invention preferably further includes a substrate coating station 135. The substrate 140 coated at substrate coating station 135 may be any substrate known in the art as coatable using conventional vapor deposition processes. Examples of suitable substrates include glass and polymeric films. At least one surface 145 of substrate 140 is placed in contact with evaporant 190 at substrate coating station 135 such that evaporant condenses on the surface 145 and forms a coating thereon. Substrate coating station 135 is preferably adjacent to evaporant chamber 125; however, it will be understood by one of ordinary skill that in certain embodiments is may desirable for coating station 135 to be located within the evaporant chamber 125. The device preferably further includes at least one ion source 165 for treating surface 145 of substrate 140 with at least one ion stream of a given intensity (multiple ion streams with total intensity C are generally shown at 170 of FIG. 1). More particularly, the ion source 165 projects accelerated ion streams that treat (i) the surface 145 of the substrate 140 concurrently with the substrate's contact with evaporant 190 or (ii) the coating formed by evaporant's condensation on the surface 145 of the substrate 140 during or shortly after its formation. The ion streams 170 densify (through reducing porosity) and improve adhesion of the coating formed by evaporant's condensation on the surface 145 of the substrate 140. Preferably, the ion source is a tunable ion source that provides for tuning or adjustment and then selection of the intensity (current) of the ion stream. Intensity of the ion streams correlates to coating density through porosity manipulation such that ion stream intensity can be adjusted and/or tuned and then selected so as to achieve a desired level of coating densification. Ion sources useful in the present invention are well known in the art and are commercially available for example from Kauffman & Robinson under the name End Hall Ion Source.

In the particularly preferred embodiment shown in FIG. 1, the substrate 140 is a web or film, particularly polyethylene terephthalate (PET) film. In this embodiment, the coating station 135 may include a roll-to-roll carrier with a feed roll 155 and a take-up roll 160 for passing substrate 140 within the coating station 135.

While it will be understood by one of ordinary skill that plasma may be generated separately in a separate device and transported to heating chamber 105, the device of the present invention preferably also includes at least one plasma source 175 to generate the plasma 110 contained in the heating chamber 105. Plasma, as the term is used herein, is meant to include any gaseous material in which a significant percentage of the atoms or molecules are ionized. As known in the art, plasma is considered a higher energy state of matter where positively charged particles and negatively charged particles are both present, forming a quasi-neutral gas. Plasma sources are well known in the art and are typically made of electrodes that are in contact with a gas and connected to a relatively high voltage. Plasma source 175 may be selected from any plasma generators well known in the art, including hollow cathode, bipolar hollow cathode types such as is disclosed in U.S. Pat. No. 6,444,945, assigned to the assignee of the present invention, glow discharge or other suitable type. Hollow cathode plasma generators are preferred. The power source for the plasma source may be DC or AC current. The plasma source 175 may be “point” or “linear” in form and the device may include multiple plasma sources. Preferably plasma source 175 is integral with the device of the present invention.

It is an important aspect of the present invention that, since the plasma does not physically contact, interact or react with the evaporant 130 or the evaporant source 115, any limitations materially influencing the choice of plasma source that might arise from such contact, interaction or reaction are rendered moot.

Evaporant source 115 is optionally retained in an evaporant source retainer 120. The term “retainer” is not intending to be limiting but includes any structure that is capable of actively holding, retaining or clasping an evaporant source as well as structures capable of passively containing or supporting the evaporant source. Examples include liners and crucibles made of graphite, refractory metals, metal oxides, and combinations thereof.

Evaporant source retainer 120 is preferably located inside chamber 125 such that evaporant source 115 is housed in evaporant chamber 125. In this embodiment, evaporant chamber 125 and heating chamber 105 are separated by wall 185. Wall 185 separating the heating chamber 105 and the evaporant chamber 125 may be an integral component of one or both of the heating chamber 105 and evaporant chamber 125 or may be a separate structure and is preferably formed from a high heat-transfer material, for example graphite.

It will be understood by one skilled in the art that the materials for construction of the device of the present invention and its components will be selected based on many factors, including for example chemical reactivity and compatibility, system operating conditions and temperature. For example, materials such as tungsten, niobium, tantalum and the like will be required for higher temperature (e.g. 1400° C.) operating conditions, while devices for use in lower temperature (e.g. 600° C.) operating conditions may be constructed from stainless steel, titanium and the like.

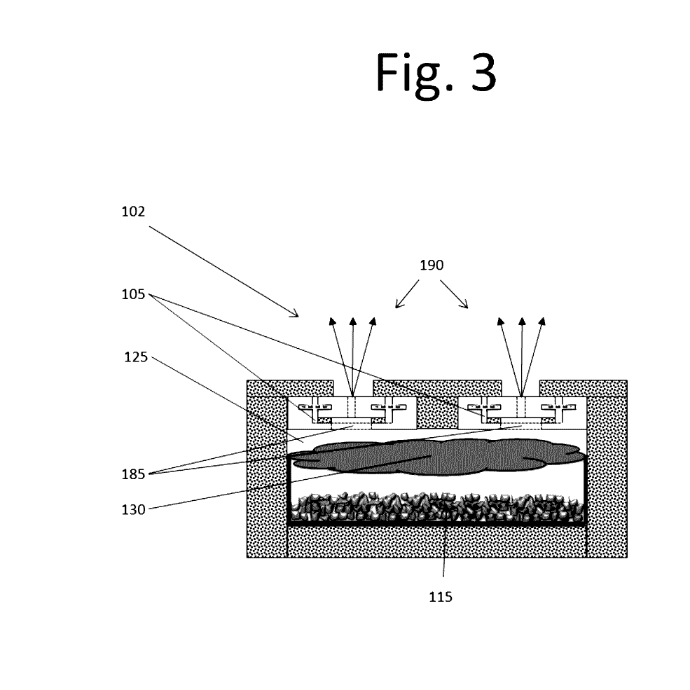

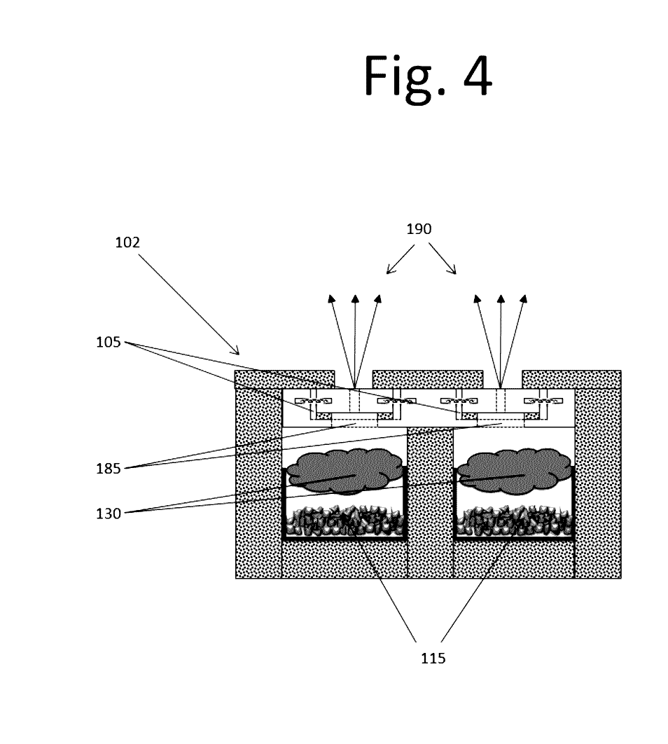

In utilities where final coating uniformity is of paramount interest, a preferred embodiment of the vapor deposition device of the present invention may include an evaporant generation assembly with multiple heating chambers, multiple evaporant chambers, or both. In this embodiment, output of the multiple evaporant streams 190 can be varied and/or can overlap thereby minimizing potential influences from variability in process parameters such as gas distribution shape, gas pressure, source geometry, differences in individual evaporation stream rates and the like. By way of non-limiting examples, the evaporant generation assembly 102 depicted in FIG. 3 includes two heating chambers 105 each separated from a single evaporant chamber 125 by walls 185 while the evaporant generation assembly 102 depicted in FIG. 4 includes a single heating chamber 105 and two evaporant chambers 1425 each separated from heating chamber 105 by walls 185.

The evaporant source 115 may be selected from materials known in the coating art as evaporant sources for conventional deposition processes. Examples include metals, metal oxides, fluorides and sulfides. The evaporant source 115 may be in solid or liquid form.

In one embodiment, the evaporant 130 is substantially the same material or composition as the evaporant source 115 which has been converted without chemical reaction to a gaseous state or vapor. Accordingly, examples of suitable evaporant for this embodiment include metals, metal oxides, fluorides and sulfides. In another embodiment, the evaporant is an evaporant reaction product formed by reaction of the evaporant with a reactant, typically in gas or vapor form, which is present when the evaporant is generated or which is intentionally placed in reactive contact with the evaporant as or after it is formed, more preferably by injecting the reactant nearby streams 190. The chemical make-up of any evaporant reaction product will depend on many factors, including for example the selection of the evaporant and reactant, and may include for example, an oxide, nitride or similar material.

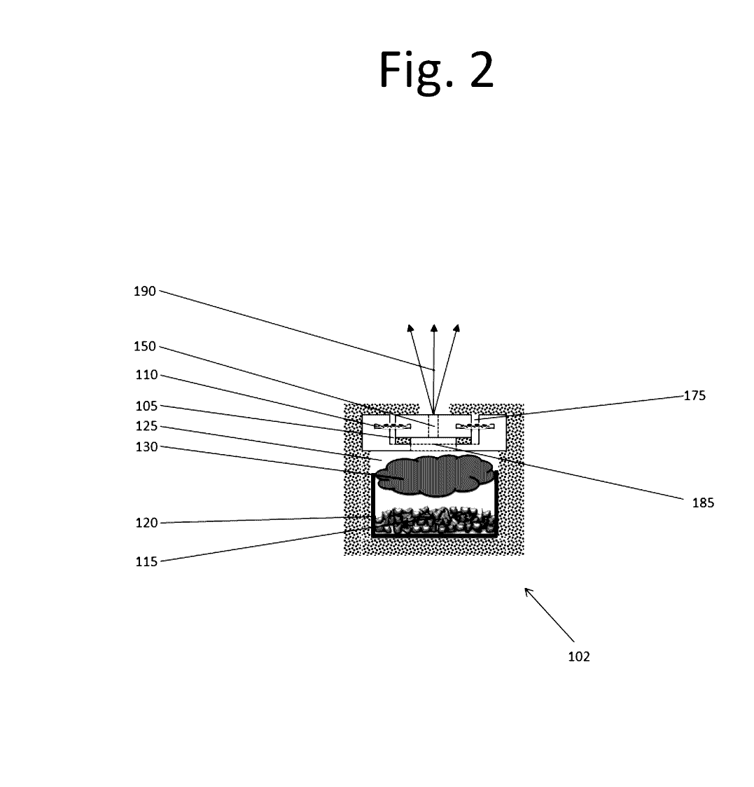

While the device of the present invention has been described above in the context of the vapor deposition art, it should be appreciated by one of ordinary skill that, in particular with regard to use of plasma as the heating media, the assembly 102 of the present invention provides a useful device for non-contact plasma heating of an evaporant source to form an evaporant is disclosed. Accordingly, as depicted in FIGS. 2, 3 and 4, such a device would include a heating chamber 105 for containing plasma and an evaporant chamber 125 for containing evaporant source 115. In the device for non-contact plasma heating of the present invention, evaporant 130 is generated by heating of the evaporant 115 source by the plasma 130 and the heating chamber is both separated from the evaporant chamber and in thermally conductive connectivity with the evaporant source.

A further aspect of the present invention is a method for depositing a coating on a substrate. The method for depositing a coating on a substrate includes supplying plasma to a heating chamber; heating an evaporant source by transfer of heat from the plasma to in an amount sufficient to generate evaporant from the evaporant source; and condensing the evaporant on a surface of the substrate to form a coating thereon. The plasma is maintained in isolation from the evaporant source and the evaporant. As used here, the phrase “maintained in isolation from” means does not and cannot physically contact or interact or chemically react. Accordingly, the plasma in the method of the present method does not and cannot physically interact or contact or chemically react with either the evaporant or the evaporant source.

The evaporant source is heated to a temperature sufficient to generate evaporant at a vapor pressure suitable to form a coating on the substrate. The method preferably includes maintaining the temperature to which the evaporant source is heated as required to obtain a constant flux of evaporant that is continuously condensing on the substrate. As known in the art, such temperatures will vary in part by the choice of evaporant source and its initial physical state. Particularly advantageous coatings may be formed by choosing evaporant sources requiring a heating step to generate evaporant of greater than 2000° C.; however, suitable coatings may be formed by choosing evaporant sources requiring a heating step to generate evaporant of 600° C. to 2200° C., preferably 1000° C. to 2200° C. and more preferably 1400° C. to 2200° C.

In the embodiment of the present method that includes forming an evaporant reaction product, the method includes forming an evaporant reaction product by reacting the evaporant with a reactant prior to or in conjunction with the condensing step. The reactant, typically in gas or liquid form, may be present when the evaporant is produced or may be placed in reactive contact with the evaporant as or after it is formed, for example by injecting the reactant nearby the evaporant streams.

In an embodiment where the method is a method for depositing a coating on a web or film substrate, particularly polyethylene terephthalate (PET) film substrate, the method may additionally include feeding the substrate from a feed roll 155 to a take-up roll 160 roll in conjunction with the condensing step. In this embodiment, the method of the present invention may, alone or in combination with the feeding step, further include projecting at least one ion stream having an intensity (multiple ion streams with intensity C are generally shown at 170 of FIG. 1) from at least one ion source 165 at the surface 145 of the substrate 140 in conjunction with condensing the evaporant on a surface 145 of the substrate 140 to form the coating thereon. As noted previously, the ion streams 170 densify and improve adhesion of the coating formed by evaporant's condensation on the surface 145 of the substrate 140. The ions streams 170 may also improve reaction rate when the coating composition is different composition from the evaporant 190, resulting from the reaction from the evaporant 190 and a reactant to form an evaporant reaction product. The method may further include selecting the intensity of the ion stream so as to achieve a desired level of coating densification.

That which is claimed is:

1. A vapor deposition device for forming a coating on a substrate and that utilizes plasma as an indirect heating medium to generate evaporant from an evaporant source, said device comprising (i) a heating chamber for containing said plasma and (ii) an evaporant chamber for containing an evaporant source;
wherein an evaporant is generated by heating of said evaporant source by said plasma and wherein said heating chamber is both separated from said evaporant chamber and in thermally conductive connectivity with said evaporant chamber.

2. The device of claim 1 further comprising at least one plasma source.

3. The device of claim 1 further comprising a substrate coating station adjacent to said evaporant chamber.

4. The device of claim 1 further comprising a substrate coating station within said evaporant chamber.

5. The device of claim 3 wherein said substrate coating station comprises a roll-to-roll carrier including a feed roll and a take-up roll for passing said substrate within said substrate coating station.

6. The device of claim 3 further comprising at least one ion source for treating said coating or a surface of said substrate with an ion stream.

7. The device of claim 5 further comprising at least one ion source for treating said coating or a surface of said substrate with an ion stream.

8. The device of claim 6 wherein said ion source is a tunable ion source that provides for tuning or adjustment of the intensity of said ion stream.

9. The device of claim 1 further comprising an evaporant source retainer contained within said evaporant chamber.

10. A method for depositing a coating on a substrate, said method comprising supplying plasma to a heating chamber; heating an evaporant source by transfer of heat from said plasma to in an amount sufficient to generate evaporant from said evaporant source; and condensing said evaporant or a reaction product thereof on a surface of said substrate to form a coating thereon;
wherein said plasma is maintained in isolation from said evaporant source and said evaporant.

11. The method of claim 10 wherein said heating step comprises heating said evaporant source to a temperature sufficient to generate evaporant at a vapor pressure suitable to form a coating on the substrate.

12. The method of claim 10 further comprising maintaining said temperature as required to obtain a constant flux of said evaporant that is continuously condensing on said substrate.

13. The method of claim 11 wherein said temperature is greater than 2000° C.

14. The method of claim 11 wherein said temperature is between 600° C. and 2200° C.

15. The method of claim 11 wherein said temperature is between 1400° C. and 2200° C.

16. The method of claim 10 further comprising forming an evaporant reaction product by reacting said evaporant with a reactant prior to or in conjunction with said condensing step.

17. The method of claim 10 further comprising feeding said substrate from a feed roll to a take-up roll in conjunction with said condensing step.

18. The method claim 10 further comprising projecting at least one ion stream at a surface of said substrate in conjunction with said condensing step.

19. The method claim 17 further comprising projecting at least one ion stream at a surface of said substrate in conjunction with said condensing step.

20. The method of claim 18 further comprising selecting the intensity of said ion stream so as to achieve a desired level of coating densification.
